(19) United States
(12) Patent Application Publication
(10) Pub. No.: US 2026/0011704 A1
(43) Pub. Date: Jan. 8, 2026

(54) MICRO LED ARRAYS ON GLASS SUBSTRATES FOR OPTICAL COMMUNICATIONS

(71) Applicant: Intel Corporation, Santa Clara, CA (US)

(72) Inventors: Benjamin DUONG, Phoenix, AZ (US); Vinod ADIVARAHAN, Chandler, AZ (US); Liqiang CUI, Shenzhen (CN); Brandon C. MARIN, Gilbert, AZ (US); Sandeep GAAN, Chandler, AZ (US)

(21) Appl. No.: 18/881,192

(22) PCT Filed: Aug. 4, 2022
(86) PCT No.: PCT/CN2022/110152

§ 371 Date: Jan. 3, 2025

(51) Int. Cl. H01L 25/16; G02B 6/42; G02B 6/43; H04B 10/40; H04M 1/00; H10F 39/90; H10F 55/00; H10H 29/24; H10H 29/85; H10H 29/851; H10H 29/855; H10H 29/856

(52) U.S. Cl. CPC H01L 25/167; G02B 6/4206; G02B 6/43; H04B 10/40; H10F 39/90; H10F 55/00; H10H 29/24; H10H 29/8508; H10H 29/855; H10H 29/857; G02B 6/4213; G02B 6/4214; H04M 1/003; H10H 29/851; H10H 29/856

(57) ABSTRACT

Embodiments disclosed herein include optical communication modules and optoelectronic packages. In an embodiment, an optical communication module comprises a substrate, a transistor over the substrate, an array of micro light emitting diodes (LEDs) over the transistor, and a connector over the array of micro LEDs.

### TECHNICAL FIELD

Embodiments of the present disclosure relate to optoelectronic packages, and more particularly to optical communication systems that include micro-LED arrays provided on glass substrates.

### BACKGROUND

Future serializer/deserializer (SerDes) requirements will significantly increase power consumption for electrical and optical communications. One solution to the increase in power consumption is to decrease the electrical SerDes distance between the electrical die and the photonic engine.

However, it is to be appreciated that reducing the SerDes distance is not without issue. Particularly, the light source for the photonic engine is commonly a group III-V semiconductor laser or a silicon photonics laser. Such devices are sensitive to temperature increases. That is, above a certain temperature (e.g., 80° C.), the laser stops functioning properly. This is problematic because the electrical die operates at relatively high temperatures. As such, thermal performance issues limit how much the SerDes distance can be decreased.

### BRIEF DESCRIPTION OF THE DRAWINGS

FIG. 1A is a cross-sectional illustration of an optoelectronic module with an array of micro light emitting diodes (LEDs) for the light source of the photonic engine, in accordance with an embodiment.

FIG. 1B is a cross-sectional illustration of an optoelectronic module with an array of micro LEDs that further includes a lens or mirror structure, in accordance with an embodiment.

FIG. 2 is a cross-sectional illustration of a portion of an optoelectronic module that illustrates a thin film transistor (TFT) and an individual micro LED of the array of micro LEDs, in accordance with an embodiment.

FIG. 3A is a cross-sectional illustration of an optoelectronic module with a TFT array that is built into the substrate, in accordance with an embodiment.

FIG. 3B is a cross-sectional illustration of an optoelectronic module with driving circuitry for the array of micro LEDs integrated into the electronic die, in accordance with an embodiment.

FIGS. 4A-4F are cross-sectional illustrations depicting a process for forming an optoelectronic module, in accordance with an embodiment.

FIG. 5 is a cross-sectional illustration of an optoelectronic module coupled to a board, in accordance with an embodiment.

FIG. 6A is a cross-sectional illustration of a photonics engine that includes a transmit module and a receive module, in accordance with an embodiment.

FIG. 6B is a cross-sectional illustration of a photonics engine with a multiplexer and a demuxer, in accordance with an embodiment.

FIG. 7A is a cross-sectional illustration of an optoelectronic system with a photonics engine bonded to a backside of the electrical die, in accordance with an embodiment.

FIG. 7B is a cross-sectional illustration of an optoelectronic system with a photonics engine bonded to an interposer, in accordance with an embodiment.

FIG. 7C is a cross-sectional illustration of an optoelectronic system with a photonics engine bonded to a board, in accordance with an embodiment.

FIG. 8 is a schematic of a computing device built in accordance with an embodiment.

### EMBODIMENTS OF THE PRESENT DISCLOSURE

Described herein are optoelectronic packages that include optical communication systems that include micro-LED arrays provided on glass substrates, in accordance with various embodiments. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

As noted above, reducing the SerDes distance between the electrical die and the photonics engine is necessary in order to reduce power demands on the system. However, this results in subjecting the photonics engine to higher temperatures that may not be compatible with existing group III-V laser or silicon photonics technologies. Accordingly, embodiments disclosed herein use an array of micro light emitting diodes (LEDs) in order to provide the light for the system. Micro LEDs are compatible with higher temperatures, and performance is not significantly diminished by bringing the array of micro LEDs close to the hot electrical die. For example, micro LEDs have been shown to perform with minimal degradation up to temperatures of approximately 250° C.

As used herein, micro LEDs may refer to LED devices that have dimensions that are less than approximately 100 μm. Micro LEDs may operate with wavelengths between 350 nm and 800 nm in some instances. Additionally, filters (e.g., quantum dot filters) may be used to change the wavelength of a given micro LED device. In addition to improved thermal performance, micro LEDs are also generally characterized as a low power substitute to silicon photonics devices. For example, powers as low as approximately 0.1 pJ/bit to approximately 0.5 pJ/bit have been demonstrated, compared to approximately 5 pJ/bit for silicon photonics devices. As used herein, “approximately” may refer to a range of values that is within 10% of the stated value. For example, approximately 100 μm may refer to a range between 90 μm and 110 μm.

In an embodiment, micro LEDs described herein may be any suitable micro LED material system. In a particular embodiment, the micro LEDs may include InGaN, AlInGaP, or the like. In some embodiments, the micro LEDs may be grown on the underlying substrate. That is, micro LEDs may be fabricated in line with the photonics engine. In other embodiments, the micro LEDs may be grown on donor wafers, and the micro LEDs may be placed on the target substrate with a pick and place operation. Such a configuration may be particularly beneficial in embodiments where micro LEDs with different wavelengths are provided in the same photonics engine.

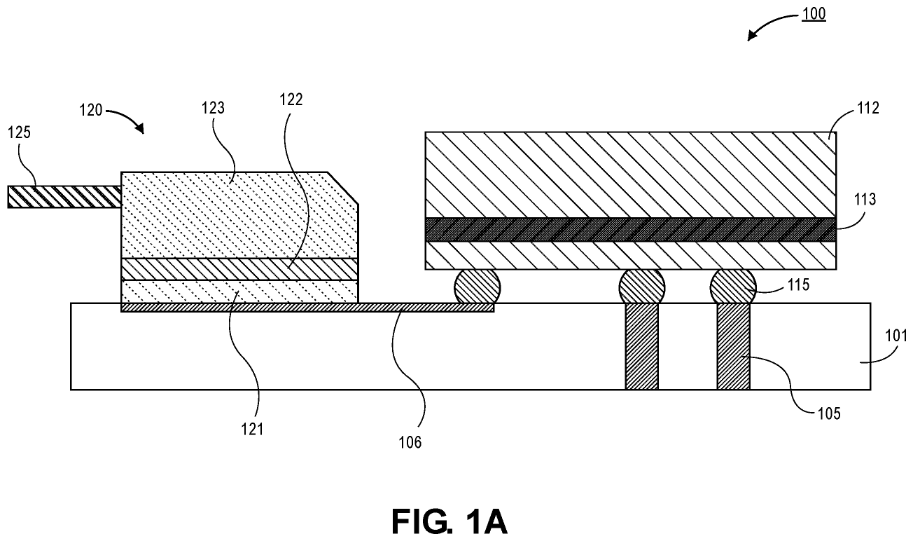

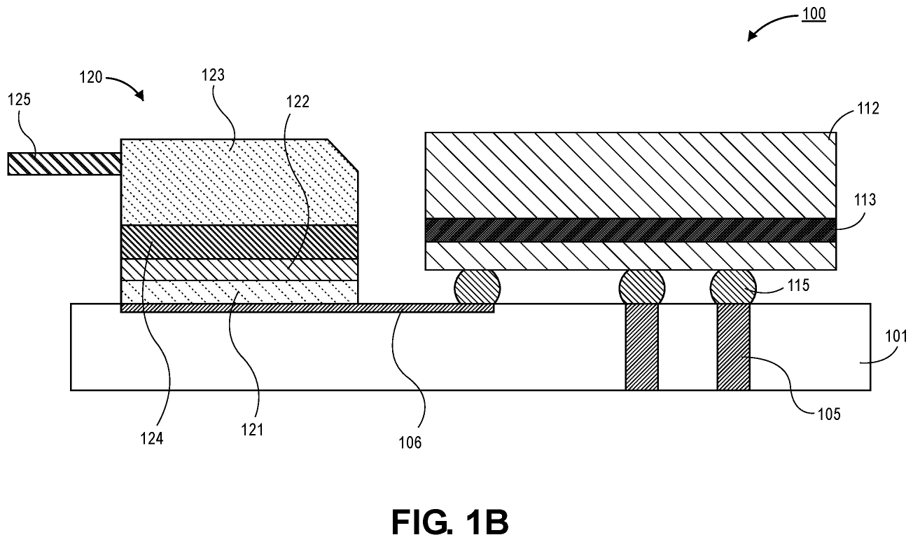

Referring now to FIG. 1A, a cross-sectional illustration of an optoelectronic module 100 is shown, in accordance with an embodiment. In an embodiment, the optoelectronic module 100 may comprise a substrate 101. The substrate 101 may be any suitably rigid substrate that is compatible with high temperature environments. For example, the substrate 101 may comprise glass, silicon, or the like. In the case of a silicon substrate 101, the substrate 101 may be an active substrate (as will be described in greater detail below). In an embodiment, the substrate 101 may include conductive features such as vias 105 and traces 106. The vias 105 may allow for power to be delivered through a thickness of the substrate 101 and allow for vertical integration of the optoelectronic module 100. The traces 106 may provide electrical coupling between an electronic die 112 and the photonics module 120. While shown as being embedded in the substrate 101, in some other embodiments, the traces 106 may be disposed on a top surface of the substrate 101.

In an embodiment, the die 112 may be an electronic integrated circuit (EIC). The die 112 may include an active transistor layer 113. The active transistor layer 113 may be coupled to the trace 106 through back-end-of-line routing (not shown) and an interconnect 115. The interconnect 115 may comprise a solder ball, a copper bump, hybrid bonding, or any other first level interconnect (FLI) architecture.

In an embodiment, the photonics module 120 may include a transistor layer 121. The transistor layer 121 may include thin film transistors (TFTs). The TFTs may be fabricated over the substrate 101 using standard TFT materials and processes. In an embodiment, the transistor layer 121 includes the driving circuitry used to operate one or more micro LEDs in the micro LED layer 122. The micro LED layer 122 may be provided over the transistor layer 121. The micro LED layer 122 may comprise an array of micro LEDs (not individually shown in FIG. 1A). The micro LEDs may include any micro LED, such as those described in greater detail above. In an embodiment, each micro LED may be electrically coupled to a set of TFTs in the transistor layer. The micro LEDs may be fabricated directly over the transistor layer 121, or the micro LEDs may be attached to the transistor layer 121 using pick and place operations. In an embodiment, the micro LED layer 122 may comprise ten or more individual micro LEDs. For example, the micro LED layer 122 may comprise one hundred or more micro LEDs in some embodiments.

In an embodiment, the micro LED layer 122 may be coupled to one or more optical fibers 125 through a connector 123. The connector 123 may be a mechanical device that orients the fibers 125 so that they are optically coupled to one or more of the micro LEDs in the micro LED layer 122. In the illustrated embodiment, the optical fibers 125 are oriented horizontally, but it is to be appreciated that the optical fibers 125 may have any orientation coming into the connector 123, such as a vertical orientation. In some embodiments, the photonics module 120 is configured to operate with parallel signaling. In other embodiments, the photonics module 120 is configured to operate with serial signaling. In yet another embodiment, the photonics module 120 may be configured to operate with both parallel and serial signaling. In an embodiment, both ends of the optical fiber 125 may be coupled to photonics modules similar to photonics module 120. In other embodiments, one end of the optical fiber 125 may be directly coupled to a waveguide in the substrate 101.

Referring now to FIG. 1B, a cross-sectional illustration of an optoelectronic module 100 is shown, in accordance with an additional embodiment. In an embodiment, the optoelectronic module 100 may be substantially similar to the optoelectronic module 100 in FIG. 1A, with the exception of the structure of the photonics module 120. Particularly, the photonics module 120 may further include a modifier layer 124. The modifier layer 124 may include functionality to modify the light emitted by the micro LEDs of the micro LED layer 122. For example, the modifier layer 124 may include functionality to change the direction or focus of the light. That is, the modifier layer 124 may include one or more lenses, mirrors, or the like. In other embodiments, the modifier layer 124 may include functionality to change the wavelength of the light. For example, the modifier layer 124 may include filters or the like. In a particular embodiment, the filters may include quantum dot filters or other color converters. In yet another embodiment, the modifier layer 124 may change a polarization of the light emitted by the micro LEDs. For example, the modifier layer 124 may include one or more polarizers.

In the illustrated embodiment, the modifier layer 124 is a distinct layer that is provided between the connector 123 and the micro LED layer 122. However, in other embodiments, the modifier layer 124 may be integrated as part of the connector 123. That is, the modifier layer 124 may not be a distinct layer in some embodiments. Additionally, while shown as a single structure, the modifier layer 124 may comprise multiple individual components. For example, each micro LED may be optically coupled with different lenses in the modifier layer 124.

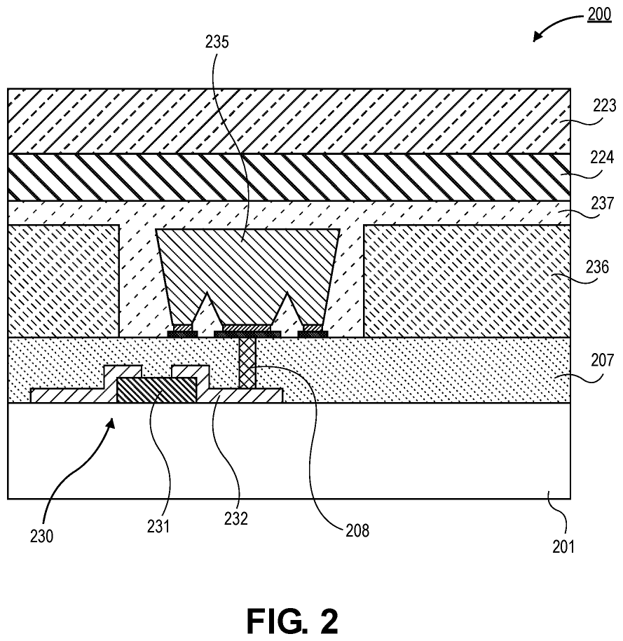

Referring now to FIG. 2, a cross-sectional illustration of a portion of an optoelectronic module 200 is shown, in accordance with an embodiment. The optoelectronic module 200 may comprise a substrate 201. The substrate 201 may be a glass substrate 201 or a silicon substrate 201. In an embodiment, a transistor 230 may be provided over the substrate 201. The transistor 230 may be part of the transistor layer 121 described in greater detail above. For example, the transistor 230 may be a TFT device. The transistor 230 may include a semiconductor layer 231 with electrodes 232 over the semiconductor layer 231. In an embodiment, at least one of the electrodes 232 may be coupled to a micro LED 235. While a single transistor 230 is shown as being coupled to the micro LED 235, it is to be appreciated that multiple transistors 230 in any suitable circuit configuration may be coupled to the micro LED 235 in order to drive and otherwise control the micro LED 235. In an embodiment, the electrode 232 may be coupled to the micro LED 235 by at least a via 208 that passes through an insulating layer 207 disposed over the substrate 201.

In an embodiment, the micro LED 235 may be provided over the insulating layer 207. The micro LED 235 may be set into a cavity formed in a layer 236. The layer 236 may be a reflective layer in some embodiments. The micro LED 235 may be directly contacted with an optical glue 237 or the like. The optical glue 237 allows for light from the micro LED 235 to pass up to the modifier layer 224. In an embodiment, the modifier layer 224 may include one or more of a filter, a color converter, a lens, a mirror, a polarizer, or the like. In an embodiment, the modifier layer 224 may modify the light before it reaches a connector 223. The connector 223 may also integrate one or more portions of the modifier layer 224. In an embodiment, the connector 223 optically couples the micro LED 235 to an optical fiber (not shown in FIG. 2).

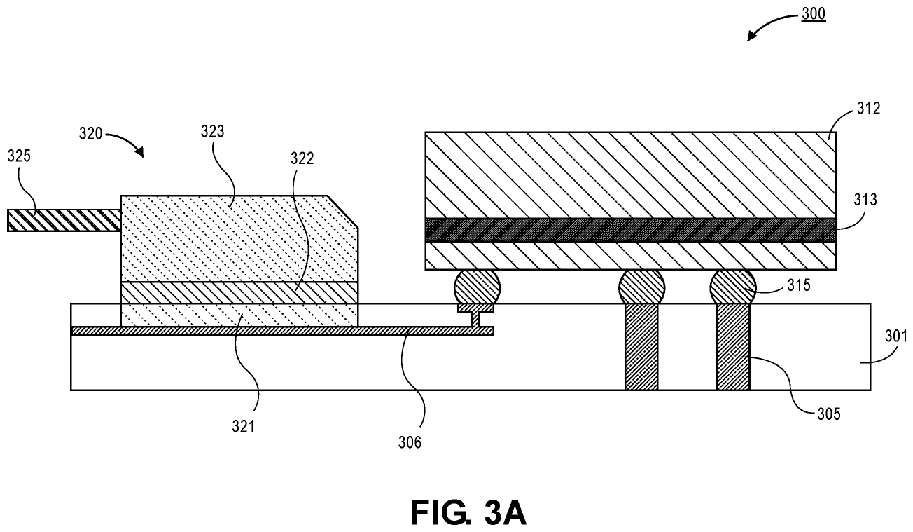

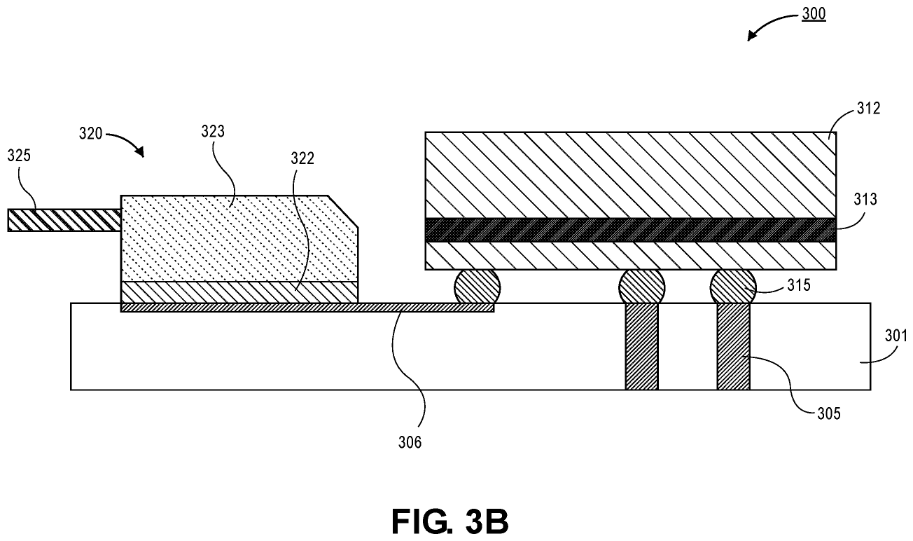

Referring now to FIG. 3A, a cross-sectional illustration of an optoelectronic module 300 is shown, in accordance with an embodiment. In an embodiment, the optoelectronic module 300 comprises a substrate 301. The substrate 301 may be a silicon substrate 301 in some embodiments. Vias 305 and traces 306 may be disposed in and/or on the silicon substrate 301. In an embodiment, an EIC 312 may be attached to the substrate 301 through interconnects 315, such as solder balls or the like. The EIC 312 may comprise an active transistor layer 313.

In an embodiment, a photonics module 320 is attached to the substrate 301. The photonics module 301 may include a transistor layer 321. The transistor layer 321 may be embedded in the substrate 301. In the case of a semiconductor substrate, such as a silicon substrate 301, the transistor layer 321 may be fabricated directly on the substrate 301. For example, transistor devices may be fabricated using traditional semiconductor processing operations (e.g., patterning, deposition, etching, etc.). While shown as being truly embedded in the substrate 301, it is to be appreciated that one or more portions of the transistor layer 321 may extend up above the semiconductor substrate 301.

In an embodiment, a micro LED layer 322 may be provided over the transistor layers 321. The micro LED layer 322 may comprise an array of micro LEDs. The micro LEDs may be controlled by transistors within the underlying transistor layer 321. In an embodiment, the micro LEDs may all be similar to each other. In other embodiments, the micro LED layer 322 may include micro LEDs that emit more than one wavelength of light. The micro LEDs may be similar to the micro LED 235 described in greater detail above.

In an embodiment, a connector 323 may optically couple the micro LED layer 322 to one or more optical fibers 325. While not shown, it is to be appreciated that the connector 323 may include one or more features of a modifier layer, such as modifier layer 124 described in greater detail above. For example, the connector 323 may include lenses, mirrors, filters, polarizers, or the like. In other embodiments, a distinct modifier layer (not shown) may be provided between the micro LED layer 322 and the connector 323.

Referring now to FIG. 3B, a cross-sectional illustration of an optoelectronic module 300 is shown, in accordance with an embodiment. In an embodiment, the optoelectronic module 300 in FIG. 3B may be substantially similar to the optoelectronic module 300 in FIG. 3A, with the exception of the transistor layer. In FIG. 3B, the transistor layer 321 is omitted from the structure. Instead, the driving circuitry for the micro LED layer 322 may be integrated into the EIC 312. For example, driving circuitry for the micro LED layer 332 may be implemented in the active transistor layer 313 of the EIC 312. As such, complexity of the photonics module 320 may be reduced. In an embodiment, the driving circuitry may be offloaded to the EIC 312 without significant issues because of the proximity of the photonics module 320 to the EIC 312.

As shown, the photonics module 320 may include a micro LED layer 322. The micro LED layer 322 may be disposed directly onto the substrate 301. For example, traces 306 embedded in the substrate 301 may directly contact the micro LEDs of the micro LED layer 322. A connector 323 that couples the micro LEDs to the one or more optical fibers 325 may also be included. The connector 323—may be substantially similar to any of the connector 123 architectures described in greater detail above.

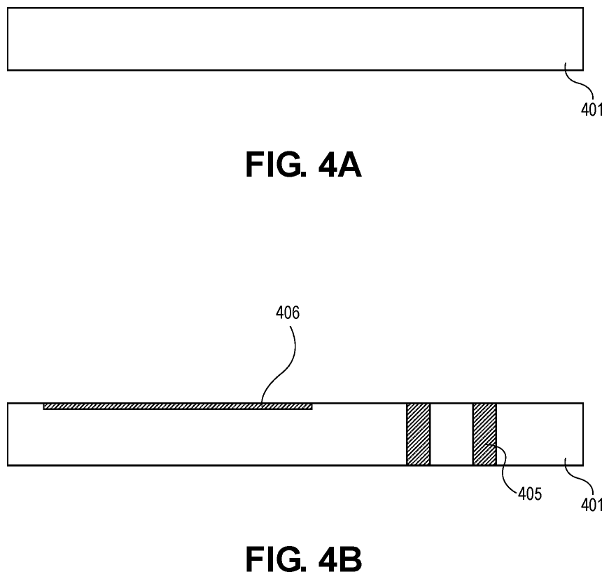

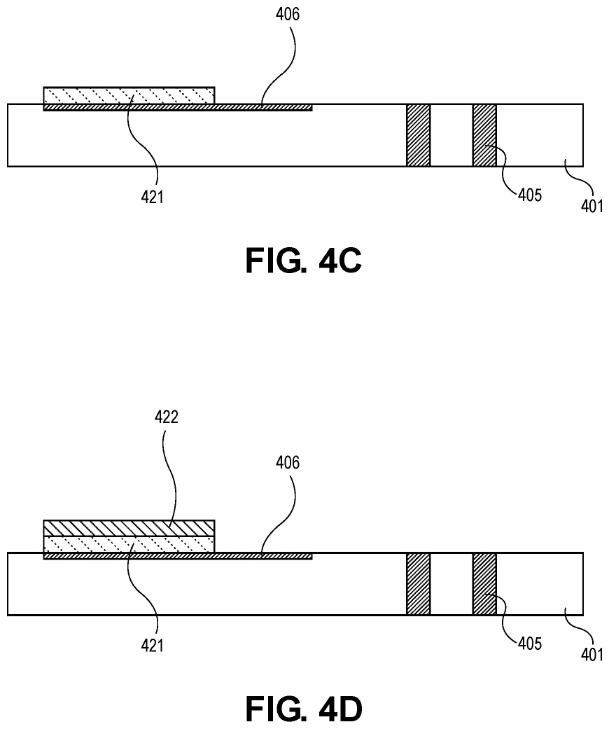

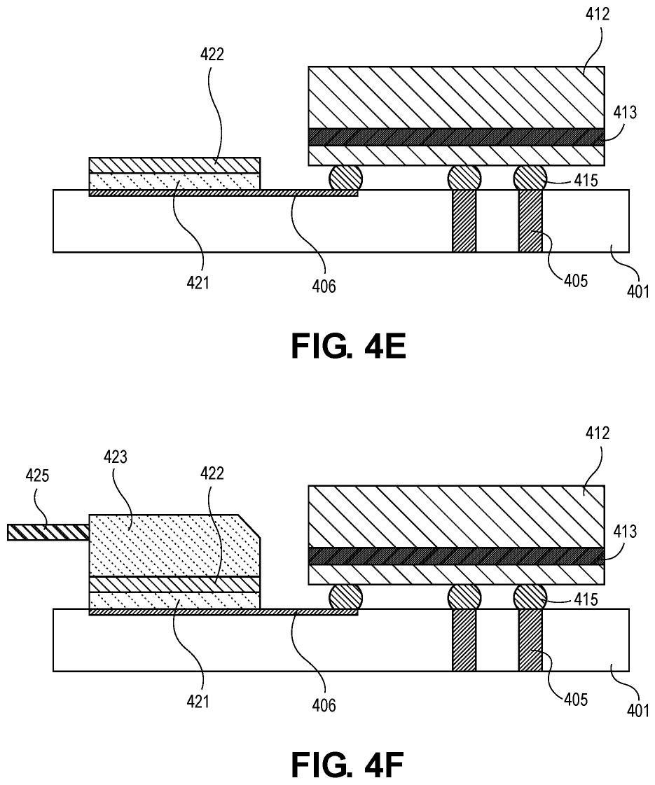

Referring now to FIGS. 4A-4F, a series of cross-sectional illustrations of a process for forming an optoelectronic module is shown, in accordance with an embodiment. In the illustrated embodiment, the optoelectronic module may be substantially similar to the optoelectronic module 100 described above with respect to FIG. 1A. However, it is to be appreciated that any of the optoelectronic modules described herein may be fabricated with similar processing operations.

Referring now to FIG. 4A, a cross-sectional illustration of a substrate 401 is shown, in accordance with an embodiment. In an embodiment, the substrate 401 may comprise any suitable rigid and high temperature compatible substrate. For example, the substrate 401 may comprise glass or a semiconductor material, such as silicon. In the illustrated embodiment, a single optoelectronic module is fabricated on the substrate 401. However, it is to be appreciated that the substrate 401 may be sized to accommodate a plurality of optoelectronic modules that can be built substantially in parallel with each other.

Referring now to FIG. 4B, a cross-sectional illustration of the substrate 401 after electrical routing is fabricated on and/or in the substrate 401 is shown, in accordance with an embodiment. In an embodiment, conductive traces 406 may be fabricated in the substrate 401. In the illustrated embodiment, the traces 406 are embedded in the substrate 401. However, it is to be appreciated that the traces 406 may also be formed on a top surface of the substrate 401 in some embodiments. The traces 406 may be fabricated with any suitable deposition and/or patterning process common in the art of semiconductor manufacturing. In an embodiment, one or more vias 405 may also be formed through a thickness of the substrate 401. A laser drilling process, a wet etching process, a dry etching process, or the like may be used in order to form via openings through the substrate 401. While shown as having substantially vertical sidewalls, it is to be appreciated that the vias 405 may have sloped sidewalls as a result of the process for forming the via openings. After the via openings are formed, conductive material may be disposed in the via openings to form the vias 405.

Referring now to FIG. 4C, a cross-sectional illustration of the optoelectronic module after a transistor layer 421 is formed is shown, in accordance with an embodiment. In an embodiment, the transistor layer 421 may comprise a plurality of transistors that are to function as the driving circuitry for the overlying micro LEDs. The driving circuitry may have any suitable circuit configuration. In a particular embodiment, the transistor layer 421 may be formed with TFT technology. That is, a thin layer of semiconductor material may be deposited and patterned, and electrical contacts may be provided over the semiconductor material. While TFT devices may be particularly beneficial due to their ease of fabrication, it is to be appreciated that any transistor architecture may be used to form the transistor layer 421. In an embodiment, the transistor layer 421 may be provided above the substrate 401. The transistor layer 421 may be contacted from below by the one or more traces 406. Alternatively, the transistor layer 421 may be contacted from the side or from above by the one or more traces 406. Additionally, while not shown, it is to be appreciated that one or more redistribution layers may be provided between the transistor layer 421 and the substrate 401.

Referring now to FIG. 4D, a cross-sectional illustration of the optoelectronic module after a micro LED layer 422 is formed is shown, in accordance with an embodiment. In an embodiment, the micro LED layer 422 may comprise a plurality of micro LEDs. The micro LEDs may be controlled by driving circuitry in the underlying transistor layer 421. The micro LED layer 422 may contain all the same type of micro LED (e.g., all micro LEDs emit the same wavelength light). In other embodiments, there may be two or more different types of micro LED (e.g., different wavelengths of light may be emitted by different micro LEDs).

In an embodiment, the micro LED layer 422 may be formed with any suitable process. In one instance, the micro LED layer 422 may be formed with a pick and place operation. Such an embodiment may be particularly beneficial when different types of micro LEDs are used in the array of micro LEDs in the micro LED layer 422. In another embodiment, the micro LEDs may be grown (fabricated) on the underlying transistor layer 421.

Referring now to FIG. 4E, a cross-sectional illustration of the optoelectronic module after an EIC 412 is attached is shown, in accordance with an embodiment. In an embodiment, the EIC 412 may be a die that operates in the electronic regime. That is, optical signals from the photonics module are converted to an electrical signal for processing in the EIC 412. Alternatively, the EIC 412 provides an electrical signal to the photonics module which is then converted to an optical signal by the array of micro LEDs in the micro LED layer 422. In an embodiment, the EIC 412 may comprise an active transistor layer 413. The transistors in the active transistor layer 413 may be electrically coupled to the photonics module with the micro LED layer 422. For example, interconnects 415 may couple the EIC 412 to one or more conductive traces 406.

Referring now to FIG. 4F, a cross-sectional illustration of the optoelectronic module after a connector 423 is coupled to the micro LED layer 422 is shown, in accordance with an embodiment. In an embodiment, the connector 423 may optically couple micro LEDs in the micro LED layer 422 to one or more optical fibers 425. The connector 423 may also comprise features that alter the light emitted by the micro LEDs. For example, the connector 423 may comprise lenses, mirrors, filters, polarizers, and/or the like. In an alternative embodiment, one or more of the features (e.g., lenses, mirrors, polarizers, etc.) may be integrated as a discrete component between the connector 423 and the micro LED layer 422.

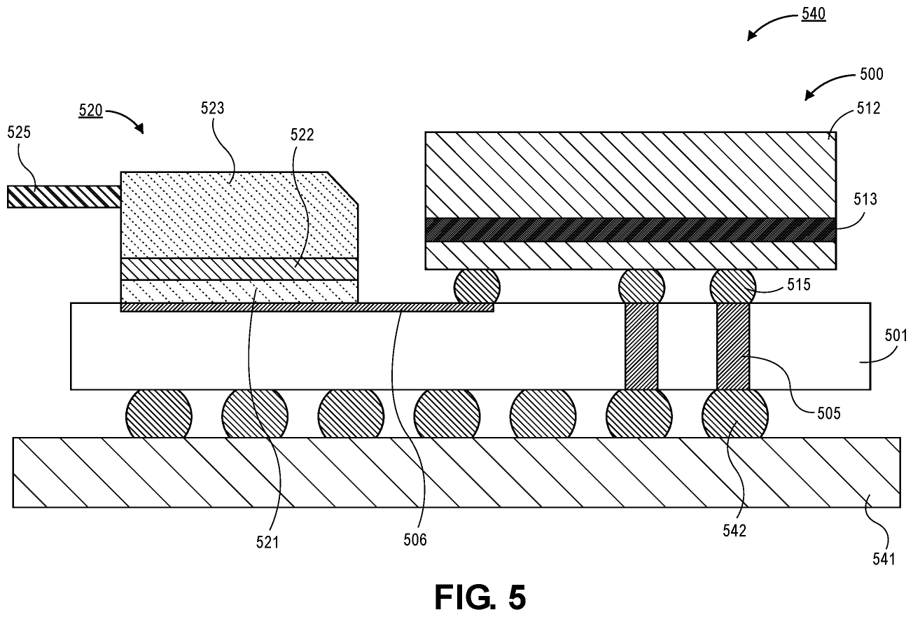

Referring now to FIG. 5, a cross-sectional illustration of an optoelectronic system 540 is shown, in accordance with an embodiment. In an embodiment, the optoelectronic system 540 may comprise a board 541, such as a printed circuit board (PCB). In an embodiment, an optoelectronic module 500 may be coupled to the board 541. For example, the board 541 may be coupled to a substrate 501 by interconnects 542. The substrate 501 may be a glass substrate, a silicon substrate, or the like. In an embodiment, conductive features, such as traces 506 and vias 505 may be formed on and/or in the substrate 501.

In an embodiment, the optoelectronic module 500 may further comprise an EIC 512. The EIC 512 may be coupled to the substrate 501 by interconnects 515. An active transistor layer 513 may be provided in the EIC 512. In an embodiment, a photonics module 520 may be coupled to the substrate 501. For example, the photonics module 520 may comprise a transistor layer 521, a micro LED layer 522, and a connector 523. The connector 523 optically couples the micro LEDs in the micro LED layer 522 to one or more optical fibers 525.

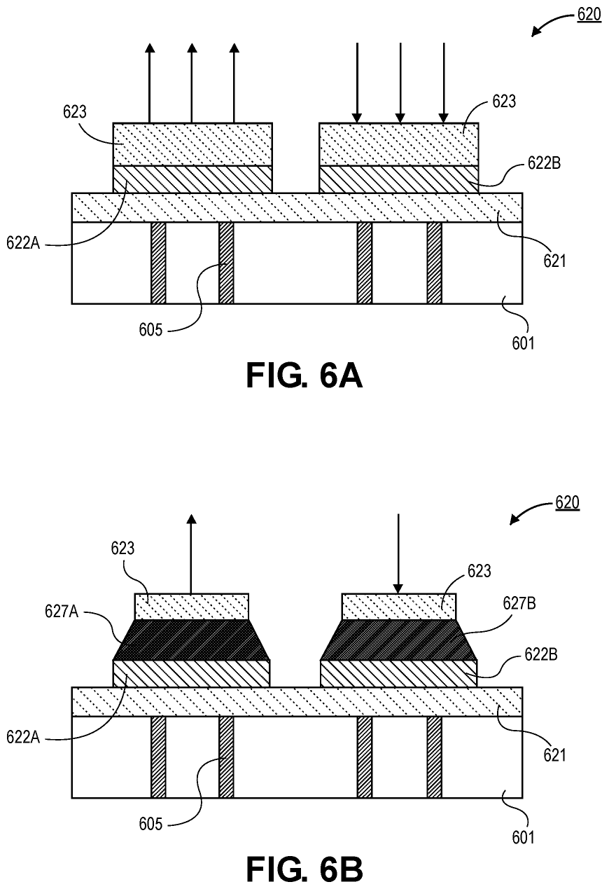

Referring now to FIG. 6A, a cross-sectional illustration of a photonics module 620 is shown, in accordance with an embodiment. In an embodiment, the photonics module 620 comprises a substrate 601. The substrate 601 may be a glass substrate 601, a silicon substrate 601, or the like. In an embodiment, one or more vias 605 may pass through a thickness of the substrate 601. In an embodiment, a transistor layer 621 may be provided over the substrate 601. The transistor layer 621 may comprise TFT devices that are used to control micro LEDs or photodiodes.

In an embodiment, the photonics module 620 may comprise a transmit side and a receive side. The transmit side may include a micro LED layer 622A. The micro LED layer 622A may comprise an array of micro LEDs. The micro LEDs may include any suitable type of micro LED, such as InGaN, AlInGaP, or the like. The micro LEDs emit light that can be used to propagate signals to an external device over optical fibers (not shown). In an embodiment, a connector 623 may optically couple the micro LED layer 622A to the optical fibers. The connector may further comprise one or more of a filter (e.g., quantum dot filters), color converters, polarizers, lenses and the like.

In an embodiment, the receive side may include a photodiode layer 622B. The photodiode layer 622B may include any type of photodiode. In some embodiments, the photodiodes are micro LEDs. In other embodiments, the photodiodes comprise SiGe, organic polymers, or the like. The photodiodes in the photodiode layer 622B may be coupled to one or more optical fibers by a connector 623. The connector may further comprise one or more of a filter, a color converter, a polarizer, and the like.

Referring now to FIG. 6B, a cross-sectional illustration of a photonics module 620 is shown, in accordance with an additional embodiment. In an embodiment, the photonics module 620 in FIG. 6B is substantially similar to the photonics module 620 in FIG. 6A, with the addition of a multiplexer 627A and a demuxer 627B. The multiplexer 627 may multiplex a plurality of signals from the micro LEDs in the micro LED layer 622A and configure their signals to be propagated along a single optical fiber, as indicated by the single arrow. Similarly, the demuxer 627B may take a multiplexed signal and divide the multiplexed signal into a plurality of signals for individual ones of the photodiodes in the photodiode layer 622B. While a single MUX/DEMUX architecture is shown, it is to be appreciated that multiple MUX/DEMUX pairs can be used to feed multiple optical fibers.

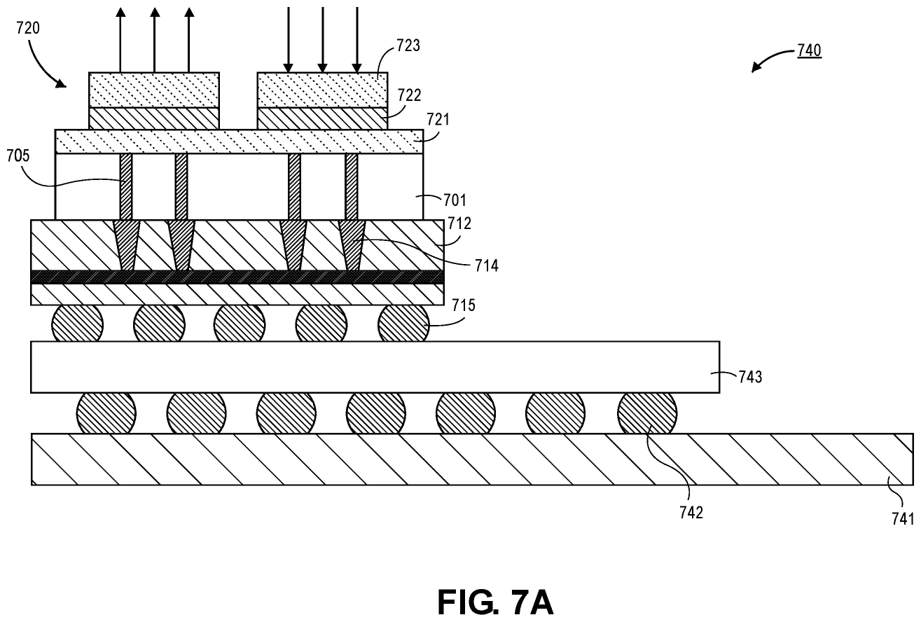

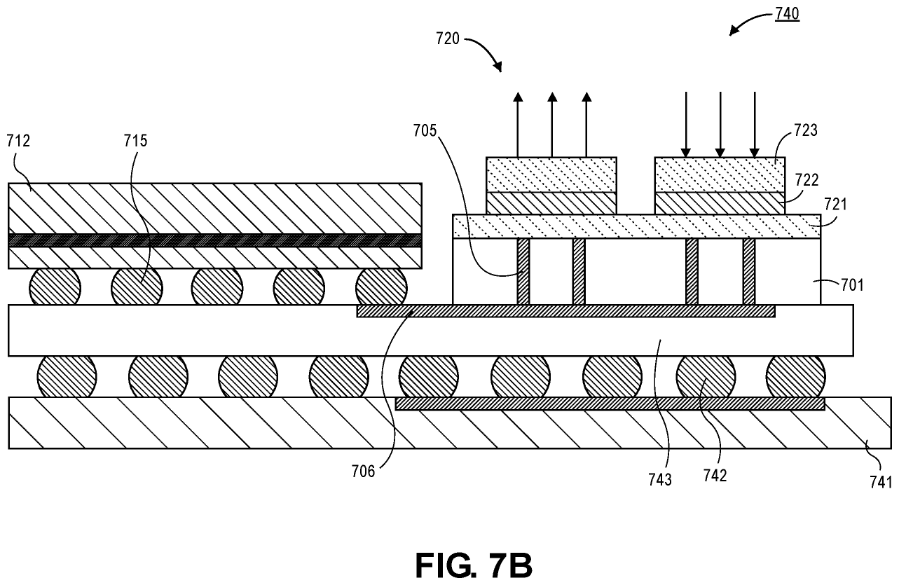

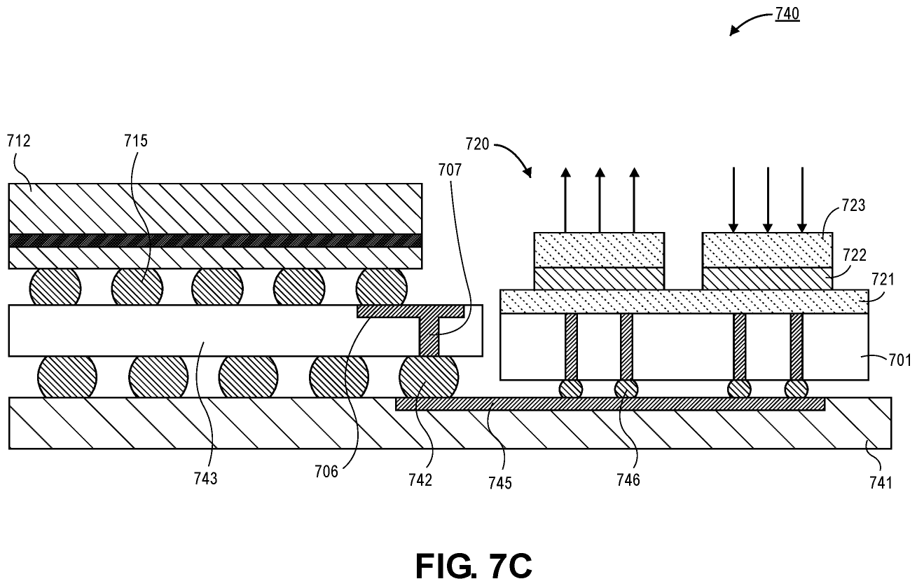

Referring now to FIGS. 7A-7C, a series of cross-sectional illustrations depicting optoelectronics systems 740 that include different placements of the photonics module 720 is shown, in accordance with an embodiment.

Referring now to FIG. 7A, a cross-sectional illustration of an optoelectronic system 740 is shown, in accordance with an embodiment. The optoelectronic system 740 may comprise a board 741, such as a PCB, and an interposer 743. The interposer 743 may be coupled to the board 741 by interconnects 742. In an embodiment, the interposer 743 may be any type of substrate, such as glass, silicon, organic, or the like. In an embodiment, an EIC 712 is coupled to the interposer 743 by interconnects 715.

In the particular embodiment shown in FIG. 7A, the EIC 712 may include through silicon vias (TSVs) 714. The TSVs 714 allow for the photonics module 720 to be directly coupled to a backside of the EIC 712. As shown, vias 705 through the substrate 701 may couple the photonics module 720 to the TSVs 714. The photonics module 720 may be similar to any of the photonics modules described in greater detail above. For example, the photonics module 720 may include a transistor layer 721 and micro LED/photodiode layers 722. Connectors 723 may optically couple the micro LEDs and photodiodes to optical fibers (not shown).

Referring now to FIG. 7B, a cross-sectional illustration of an optoelectronic system 740 is shown, in accordance with an additional embodiment. The optoelectronic system 740 in FIG. 7B may be substantially similar to the optoelectronic system 740 in FIG. 7A, with the exception of the placement of the photonics module 720. Instead of being provided over the backside of the EIC 712, the photonics module 720 is provided on the interposer 743. The photonics module 720 may be electrically coupled to the EIC 712 through a trace 706 on the interposer 743. While not shown, in some embodiments the photonics module 720 may be coupled to the interposer 743 by interconnects such as FLIs or the like. In the illustrated embodiment, a direct bonding architecture is shown.

Referring now to FIG. 7C, a cross-sectional illustration of an optoelectronic system 740 is shown, in accordance with yet another embodiment. The optoelectronic system 740 in FIG. 7C may be substantially similar to the optoelectronic system 740 in FIG. 7B, with the exception of the placement of the photonics module 720. As shown, the photonics module 720 may be mounted on the board 741. Interconnects 746 may couple the substrate 701 to the board 741. Traces 745 on the board 741, trace 706 on the interposer 743, and via 707 on the interposer 743 couple the photonics module 720 to the EIC 712.

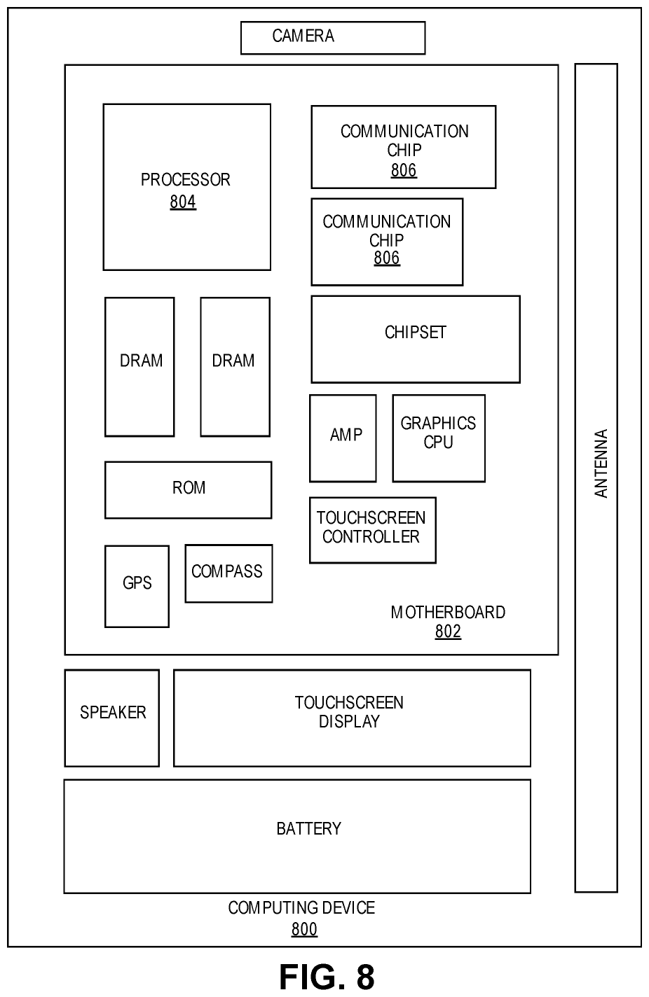

FIG. 8 illustrates a computing device 800 in accordance with one implementation of the invention. The computing device 800 houses a board 802. The board 802 may include a number of components, including but not limited to a processor 804 and at least one communication chip 806. The processor 804 is physically and electrically coupled to the board 802. In some implementations the at least one communication chip 806 is also physically and electrically coupled to the board 802. In further implementations, the communication chip 806 is part of the processor 804.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 806 enables wireless communications for the transfer of data to and from the computing device 800. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 806 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 800 may include a plurality of communication chips 806. For instance, a first communication chip 806 may be dedicated to shorter range wireless communications such as Wi-Fi and Bluetooth and a second communication chip 806 may be dedicated to longer range wireless communications such as GPS, EDGE, GPRS, CDMA, WiMAX, LTE, Ev-DO, and others.

The processor 804 of the computing device 800 includes an integrated circuit die packaged within the processor 804. In some implementations of the invention, the integrated circuit die of the processor may be part of an optoelectronic system that includes a photonics module that has an array of micro LEDs, in accordance with embodiments described herein. The term “processor” may refer to any device or portion of a device that processes electronic data from registers and/or memory to transform that electronic data into other electronic data that may be stored in registers and/or memory.

The communication chip 806 also includes an integrated circuit die packaged within the communication chip 806. In accordance with another implementation of the invention, the integrated circuit die of the communication chip may be part of an optoelectronic system that includes a photonics module that has an array of micro LEDs, in accordance with embodiments described herein.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

Example 1: an optical communication module, comprising: a substrate; a transistor over the substrate; an array of micro light emitting diodes (LEDs) over the transistor; and a connector over the array of micro LEDs.

Example 2: the optical communication module of Example 1, wherein the transistor is a thin film transistor (TFT).

Example 3: the optical communication module of Example 1 or Example 2, wherein the substrate comprises glass.

Example 4: the optical communication module of Examples 1-3, wherein the array of micro LEDs comprises micro LEDs that all emit a same wavelength of light.

Example 5: the optical communication module of Examples 1-4, wherein the array of micro LEDs comprises individual micro LEDs that emit different wavelengths of light.

Example 6: the optical communication module of Example 5, further comprising: a muxing module between the array of micro LEDs and the connector.

Example 7: the optical communication module of Examples 1-6, further comprising one or more of a lens, a filter, a quantum dot filter, a polarizer, and a mirror between the array of micro LEDs and the connector.

Example 8: the optical communication module of Examples 1-7, further comprising: vias through a thickness of the substrate.

Example 9: the optical communication module of Examples 1-8, wherein the substrate comprises silicon.

Example 10: the optical communication module of Example 9, wherein the transistor is built into the substrate.

Example 11: the optical communication module of Examples 1-10, further comprising: a receive module over the substrate, wherein the receive module comprises: an array of photodiodes; and a connector over the array of photodiodes.

Example 12: the optical communication module of Example 11, wherein the array of photodiodes comprises a second array of micro LEDs.

Example 13: an optoelectronic package, comprising: a board; an interposer coupled to the board; a die coupled to the interposer; and an optical communication module coupled to the die, wherein the optical communication module comprises: a transmit module that includes an array of micro light emitting diodes (LEDs) and a connector; and a receive module that includes an array of photodiodes and a connector.

Example 14: the optoelectronic package of Example 13, wherein the optical communication module is coupled to a backside of the die.

Example 15: the optoelectronic package of Example 13 or Example 14, wherein the optical communication module is attached to the interposer, and wherein a trace on the interposer couples the optical communication module to the die.

Example 16: the optoelectronic package of Examples 13-15, wherein the optical communication module is attached to the board, and wherein the optical communication module is coupled to the die by a first trace on the board and a second trace on the interposer.

Example 17: an optoelectronic package of Examples 13-16, wherein the transmit module and the receive module are provided on a substrate.

Example 18: the optoelectronic package of Example 17, wherein the substrate comprises glass or silicon.

Example 19: an optoelectronic module, comprising: a substrate; a die on the substrate, wherein the die operates in an electrical regime; and a transmit module on the substrate and coupled to the die, wherein the transmit module comprises: a transistor layer; a micro light emitting diode (LED) layer; and a connector.

Example 20: the optoelectronic module of Example 19, wherein the substrate comprises glass or silicon.

Example 21: the optoelectronic module of Example 19 or Example 20, further comprising: a lens and/or mirror between the micro LED layer and the connector.

Example 22: the optoelectronic module of Examples 19-21, wherein the transistor layer is embedded in the substrate.

Example 23: the optoelectronic module of Examples 19-22, wherein the transmit module is configured to transmit signals in parallel optical signaling and/or serial optical signaling.

Example 24: an optoelectronic package, comprising: a board; an interposer coupled to the board; a die operating in an electrical regime, wherein the die is coupled to the interposer; and a photonics engine coupled to the die, wherein the photonics engine comprises: a thin film transistor (TFT) layer over the interposer; a micro LED layer over the TFT layer, wherein the micro LED layer comprises an array of micro LEDs, wherein individual ones of the micro LEDs are controlled by a set of TFTs in the TFT layer; and a connector over the micro LED layer, wherein the connector is configured to couple the array of micro LEDs to one or more optical fibers.

Example 25: the optoelectronic package of Example 24, wherein the interposer comprises glass.

What is claimed is:

1. An optical communication module, comprising:
a substrate;
a transistor over the substrate;
an array of micro light emitting diodes (LEDs) over the transistor; and
a connector over the array of micro LEDs.

2. The optical communication module of claim 1, wherein the transistor is a thin film transistor (TFT).

3. The optical communication module of claim 1, wherein the substrate comprises glass.

4. The optical communication module of claim 1, wherein the array of micro LEDs comprises micro LEDs that all emit a same wavelength of light.

5. The optical communication module of claim 1, wherein the array of micro LEDs comprises individual micro LEDs that emit different wavelengths of light.

6. The optical communication module of claim 5, further comprising:
a muxing module between the array of micro LEDs and the connector.

7. The optical communication module of claim 1, further comprising one or more of a lens, a filter, a quantum dot filter, a polarizer, and a mirror between the array of micro LEDs and the connector.

8. The optical communication module of claim 1, further comprising:
vias through a thickness of the substrate.

9. The optical communication module of claim 1, wherein the substrate comprises silicon.

10. The optical communication module of claim 9, wherein the transistor is built into the substrate.

11. The optical communication module of claim 1, further comprising:
a receive module over the substrate, wherein the receive module comprises:
an array of photodiodes; and
a connector over the array of photodiodes.

12. The optical communication module of claim 11, wherein the array of photodiodes comprises a second array of micro LEDs.

13. An optoelectronic package, comprising:
a board;
an interposer coupled to the board;
a die coupled to the interposer; and
an optical communication module coupled to the die, wherein the optical communication module comprises:
a transmit module that includes an array of micro light emitting diodes (LEDs) and a connector; and
a receive module that includes an array of photodiodes and a connector.

14. The optoelectronic package of claim 13, wherein the optical communication module is coupled to a backside of the die.

15. The optoelectronic package of claim 13, wherein the optical communication module is attached to the interposer, and wherein a trace on the interposer couples the optical communication module to the die.

16. The optoelectronic package of claim 13, wherein the optical communication module is attached to the board, and wherein the optical communication module is coupled to the die by a first trace on the board and a second trace on the interposer.

17. The optoelectronic package of claim 13, wherein the transmit module and the receive module are provided on a substrate.

18. The optoelectronic package of claim 17, wherein the substrate comprises glass or silicon.

19. An optoelectronic module, comprising:
a substrate;
a die on the substrate, wherein the die operates in an electrical regime; and
a transmit module on the substrate and coupled to the die, wherein the transmit module comprises:
a transistor layer;
a micro light emitting diode (LED) layer; and
a connector.

20. The optoelectronic module of claim 19, wherein the substrate comprises glass or silicon.

21. The optoelectronic module of claim 19, further comprising:
a lens and/or mirror between the micro LED layer and the connector.

22. The optoelectronic module of claim 19, wherein the transistor layer is embedded in the substrate.

23. The optoelectronic module of claim 19, wherein the transmit module is configured to transmit signals in parallel optical signaling and/or serial optical signaling.

24. An optoelectronic package, comprising:
a board;
an interposer coupled to the board;
a die operating in an electrical regime, wherein the die is coupled to the interposer; and
a photonics engine coupled to the die, wherein the photonics engine comprises:
a thin film transistor (TFT) layer over the interposer;
a micro LED layer over the TFT layer, wherein the micro LED layer comprises an array of micro LEDs, wherein individual ones of the micro LEDs are controlled by a set of TFTs in the TFT layer; and
a connector over the micro LED layer, wherein the connector is configured to couple the array of micro LEDs to one or more optical fibers.

25. The optoelectronic package of claim 24, wherein the interposer comprises glass.
